(19) United States
(12) Patent Application Publication
(10) Pub. No.: US 2013/0302590 A1
(43) Pub. Date: Nov. 14, 2013

(54) FOAM LAMINATE FOR ELECTRIC OR ELECTRONIC DEVICE

(71) Applicants: Itsuhiro Hatanaka, Osaka (JP); Naomi Watanabe, Osaka (JP)

(72) Inventors: Itsuhiro Hatanaka, Osaka (JP); Naomi Watanabe, Osaka (JP)

(73) Assignee: NITTO DENKO CORPORATION, Ibaraki-shi, Osaka (JP)

(21) Appl. No.: 13/981,380

(22) PCT Filed: Jan. 16, 2012
(86) PCT No.: PCT/JP2012/050728

§ 371 Date: Jul. 24, 2013

(30) Foreign Application Priority Data
Jan. 24, 2011 (JP) 2011-012249

(51) Int. Cl. H05K 5/06

(52) U.S. Cl. CPC H05K 5/061
USPC 428/317.7

(57) ABSTRACT

The invention has an object to provide a foam laminate with excellent repeelability for electric or electronic devices. A foam laminate for electric or electronic devices of the invention has, on at least one side of a foam layer, a polyolefin-based pressure-sensitive adhesive layer containing a polyolefin, in which the polyolefin-based pressure-sensitive adhesive layer has a 180° peelability from an acrylic plate (tension rate: 0.3 m/min) of from 0.1 N/20 mm to 2.5 N/20 mm. The polyolefin-based pressure-sensitive adhesive layer is preferably a pressure-sensitive adhesive layer containing a polyolefin A having a crystal melting energy of less than 50 J/g, or a pressure-sensitive adhesive layer containing the polyolefin A and a polyolefin B having a crystal melting energy of 50 J/g or more in which a proportion of the polyolefin B is from 3 to 30% by weight with respect to a total polyolefin amount (100% by weight).

### TECHNICAL FIELD

The present invention relates to a foam laminate for electric or electronic devices. More precisely, the invention relates to a foam laminate having a pressure-sensitive adhesive layer on at least one side of a foam layer and favorably used as a gasket for electric/electronic devices (portable telephones, portable terminals, digital cameras, video movies, personal computers, liquid-crystal TVs, other home electric appliances, etc.).

### BACKGROUND ART

Regarding a foam, it is known to form a resin layer on the surface of the foam for improving the adhesiveness and the sealability of the foam. For example, for the purpose of improving the sealability thereof, there is provided a foam laminate having a flexible layer or a pressure-sensitive adhesive layer formed on the foam (see Patent Documents 1 and 2). Also proposed are a foam having an easily water-soluble layer (polyvinyl alcohol layer or the like) formed on the surface of the foam for improving the waterproofness thereof (see Patent Document 3) and a foam of which the surface is processed with a polychloroprene-based adhesive composition for expressing adhesiveness (see Patent Document 4), etc. However, these foam laminates require a heating and drying step in forming the layer on the foam, and therefore have a risk in that the foam poorly resistant to heat and having a low density would shrink in drying. When the heating temperature is lowered for preventing the shrinkage, then long-term heating for from 3 to 7 days would be needed inefficiently.

As a method not requiring the heating step in forming a resin layer on the surface of a foam, there has been proposed a technique of providing a thermoplastic elastomer on a foam through coextrusion lamination bonding (see Patent Document 5). However, the resin laminate foam obtained according to the method has a large number of irregularities on the surface of the resin layer and is therefore problematic in point of the dust-proofness thereof. Further, there has been proposed a technique of applying a hot-melt resin onto the surface of a foam (see Patent Document 6). However, since a large amount of a highly-crystalline resin is added to the hot-melt resin, there is a high possibility that the obtained resin layer would have extremely tough physical properties and, when folded, the layer may be cracked.

Further, it is known to form an acrylic pressure-sensitive layer having a high adhesion force on a foam; however, reworking in adhering the foam laminated with such an acrylic pressure-sensitive layer to an electric/electronic device is often difficult.

### BACKGROUND ART DOCUMENT

### Patent Document

Patent Document 1: JP-A 9-131822
Patent Document 2: JP-A 2002-309198
Patent Document 3: JP-A 10-37328
Patent Document 4: JP-A 5-24143
Patent Document 5: JP-A 2009-184181
Patent Document 6: JP-A 2004-284575

### SUMMARY OF THE INVENTION

### Problems that the Invention is to Solve

Accordingly, an object of the invention is to provide a foam laminate with excellent repeelability for electric or electronic devices.

Another object of the invention is to provide a foam laminate with excellent repeelability and excellent dust-proofness (especially dynamic dust-proofness) for electric or electronic devices.

Still another object of the invention is to provide a foam laminate with excellent repeelability and excellent heat resistance for electric or electronic devices.

### Means for Solving the Problems

The present inventors have assiduously studied for the purpose of solving the above-mentioned problems and, as a result, have found that, in a foam laminate having a polyolefin-based pressure-sensitive adhesive layer on at least one side of a foam layer, when the 180° peelability of the polyolefin-based pressure-sensitive adhesive layer from an acrylic plate is defined to fall within a specific range, then the foam laminate has excellent repeelability. In addition, the inventors have further found that, when the polyolefin-based pressure-sensitive adhesive layer is a polyolefin-based pressure-sensitive adhesive layer containing a specific polyolefin, then the foam laminate has excellent repeelability and excellent dust-proofness (especially dynamic dust-proofness). Based on these findings, the inventors have completed the present invention.

Namely, a foam laminate for electric or electronic devices of the invention has, on at least one side of a foam layer, a polyolefin-based pressure-sensitive adhesive layer containing a polyolefin, in which the polyolefin-based pressure-sensitive adhesive layer has a 180° peelability from an acrylic plate (tension rate: 0.3 m/min) of from 0.1 N/20 mm to 2.5 N/20 mm.

In the foam laminate for electric or electronic devices described above, the polyolefin-based pressure-sensitive adhesive layer is preferably a pressure-sensitive adhesive layer containing a polyolefin A having a crystal melting energy of less than 50 J/g, or a pressure-sensitive adhesive layer containing the polyolefin A and a polyolefin B having a crystal melting energy of 50 J/g or more in which a proportion of the polyolefin B is from 3 to 30% by weight with respect to a total polyolefin amount (100% by weight).

In the foam laminate for electric or electronic devices described above, the polyolefin-based pressure-sensitive adhesive layer is preferably a hot-melt pressure-sensitive adhesive layer having a melt viscosity at 200° C. of from 1 to 30 Pa·s.

In the foam laminate for electric or electronic devices described above, the foam layer preferably has an apparent density of from 0.02 to 0.30 g/cm³.

### Advantage of the Invention

The foam laminate of the invention has a polyolefin-based pressure-sensitive adhesive layer of which the 180° peelability from an acrylic plate falls within a specific range, and is therefore excellent in repeelability. Further, when the polyolefin-based pressure-sensitive adhesive layer therein contains a specific polyolefin, then the foam laminate of the invention is excellent in repeelability and also in dust-proofness (especially dynamic dust-proofness).

### BRIEF DESCRIPTION OF THE DRAWINGS

FIG. 1 is a chart (DSC curve) obtained in differential scanning calorimetry (DSC measurement) in Example 3.

FIG. 2 is an outline view showing an evaluation sample for use in dynamic dust-proofness evaluation.

FIG. 3 is a schematic cross-sectional view of an evaluation container fitted with an evaluation sample for dynamic dust-proofness evaluation.

FIG. 4 is a schematic view showing an evaluation method for dynamic dust-proofness test.

FIG. 5(a) is a top view of an evaluation container (evaluation container for dynamic dust-proofness evaluation) fitted with an evaluation sample; and FIG. 5(b) is a cross-sectional view of the evaluation container cut along the A-A′ line.

### MODE FOR CARRYING OUT THE INVENTION

The foam laminate for electric or electronic devices of the invention is a foam laminate having, on at least one side of the foam layer thereof, a polyolefin-based pressure-sensitive adhesive layer. The polyolefin-based pressure-sensitive adhesive layer contains a polyolefin as an essential component therein. The polyolefin-based pressure-sensitive adhesive layer is a pressure-sensitive adhesive layer of which the 180° peelability from an acrylic plate (tension rate: 0.3 m/min) is from 0.1 N/20 mm to 2.5 N/20 mm. In this application, “180° peelability from an acrylic plate (tension rate: 0.3 m/min)” may be simply referred to as “peelability from an acrylic plate (pressure-sensitive adhesive force to an acrylic plate)”. In this application, “polyolefin-based pressure-sensitive adhesive layer of which the peelability from an acrylic plate is from 0.1 N/20 mm to 2.5 N/20 mm” may be referred to as “specific polyolefin-based pressure-sensitive adhesive layer”. Further, “foam laminate for electric or electronic devices of the invention” may be simply referred to as “foam laminate of the invention”.

Not specifically defined, the foam laminate of the invention preferably has a sheet-like or tape-like form. Further, before use, the foam laminate of the invention may be worked to have a desired shape in accordance with the electric/electronic devices, apparatus, casings, parts and others to which the foam laminate is applied. The pressure-sensitive adhesive layer of the foam laminate of the invention may be protected with a release film (separator) until before use.

The foam laminate of the invention is a laminate structure that has a configuration with the specific polyolefin-based pressure-sensitive adhesive layer laminated on at least one side of the foam layer thereof, directly or via any other layer therebetween. Especially preferably, the foam laminate of the invention has a configuration where the specific polyolefin-based pressure-sensitive adhesive layer is directly laminated on one side or both sides of the foam layer.

The foam laminate of the invention may be a double-faced adhesive type having the specific polyolefin-based pressure-sensitive adhesive layer on both sides of the foam layer, or may be a single-faced adhesive type having the specific polyolefin-based pressure-sensitive adhesive layer only on one side of the foam layer. In the case where the foam laminate of the invention is a double-faced adhesive type, the foam laminate may be in any type where the pressure-sensitive adhesive layers on both sides thereof are the specific polyolefin-based pressure-sensitive adhesive layers, or the pressure-sensitive adhesive layer on one side is the specific polyolefin-based pressure-sensitive adhesive layer and the layer on the other side is any other pressure-sensitive adhesive layer (for example, any known pressure-sensitive adhesive layer, any other polyolefin-based pressure-sensitive adhesive layer than the specific polyolefin-based pressure-sensitive adhesive layer).

### (Specific Polyolefin-Based Pressure-Sensitive Adhesive Layer)

The peelability of the specific polyolefin-based pressure-sensitive adhesive layer from an acrylic plate (peel angle: 180°, tension rate: 0.3 m/min) is from 0.1 N/20 mm to 2.5 N/20 mm, preferably from 0.2 N/20 mm to 2.3 N/20 mm, more preferably from 0.5 N/20 mm to 2.0 N/20 mm. When the peelability from an acrylic plate is less than 0.1 N/20 mm, then the foam laminate could hardly exhibit the pressure-sensitive adhesiveness to the adherend to which the foam laminate is applied, and the characteristic of dust-proofness thereof may worsen. On the other hand, when the peelability from an acrylic plate is more than 2.5 N/20 mm, then the foam laminate could hardly exhibit the repeelability from the adherend to which the foam laminate is applied.

Not specifically defined, the crystal melting energy of the specific polyolefin-based pressure-sensitive adhesive layer is preferably 50 J/g or less, more preferably 45 J/g or less, even more preferably 40 J/g or less. When the crystal melting energy thereof is more than 50 J/g, then the flexibility and the pressure-sensitive slight adhesiveness of the pressure-sensitive adhesive layer would worsen, therefore providing a risk that the dust-proofness, especially the dynamic dust-proofness (dust-proofness in dynamic environments) of the pressure-sensitive adhesive layer would worsen.

In this application, the crystal melting energy is as follows: A sample is melted by heating at a heating rate of 10° C./min (first heating), and then cooled to −50° C. at a cooling rate of 10° C./min (first cooling), and thereafter again heated from −50° C. at a heating rate of 10° C./min (second heating); and in the cycle, the melting heat (J/g) of the sample in the second heating is measured through differential scanning calorimetry, and this is the crystal melting energy. The differential scanning calorimetry in determining the crystal melting energy is carried out according to JIS K 7122 (method for measuring transition heat of plastic).

The specific polyolefin-based pressure-sensitive adhesive layer contains a polyolefin as an essential component. Not specifically defined, the proportion of the polyolefin in the specific polyolefin-based pressure-sensitive adhesive layer is preferably 60% by weight or more (for example, from 60 to 100% by weight) with respect to the total amount of the polyolefin-based pressure-sensitive adhesive layer (100% by weight), more preferably 80% by weight or more (for example, from 80 to 100% by weight).

The specific polyolefin-based pressure-sensitive adhesive layer may contain only one polyolefin alone, but may contain two or more polyolefins as combined. The specific polyolefin-based pressure-sensitive adhesive layer may contain any other resin, additive and the like than polyolefin, within a range not impairing the effective advantages of the invention.

In particular, it is desirable that the specific polyolefin-based pressure-sensitive adhesive layer contains a polyolefin having a crystal melting energy of less than 50 J/g. In this application, “polyolefin having a crystal melting energy of less than 50 J/g” may be referred to as “polyolefin A”. The polyolefin A is a so-called amorphous polyolefin and does not almost have a crystal structure. When the specific polyolefin-based pressure-sensitive adhesive layer contains the polyolefin A, then the layer can readily exhibit the flexibility and the pressure-sensitive slight adhesiveness in addition to the repeelability thereof. In addition, the dust-proofness (especially dynamic dust-proofness) of the foam laminate can be improved. The specific polyolefin-based pressure-sensitive adhesive layer may contain only one type of polyolefin A, or may contain two or more different types of polyolefin A.

Specifically, the specific polyolefin-based pressure-sensitive adhesive layer is preferably a polyolefin-based pressure-sensitive adhesive layer having a peelability from an acrylic plate of from 0.1 N/20 mm to 2.5 N/20 mm, and containing the polyolefin A.

The polyolefin A is a polyolefin having a crystal melting energy of less than 50 J/g (for example, 5 J/g or more and less than 50 J/g), preferably a polyolefin having a crystal melting energy of less than 45 J/g (for example, 7 J/g or more and less than 45 J/g), more preferably a polyolefin having a crystal melting energy of less than 40 J/g (for example, 10 J/g or more and less than 40 J/g).

Not specifically defined, the polyolefin A includes, for example, low-density polyethylene, middle-density polyethylene, high-density polyethylene, linear low-density polyethylene, polypropylene, copolymer of ethylene and propylene, copolymer of ethylene and other α-olefin, copolymer of propylene and other α-olefin, copolymer of ethylene, propylene and other α-olefin, copolymer of ethylene and other ethylenic unsaturated monomer, etc. The polyolefin A may be a mixture of a homopolymer and a copolymer, or a mixture of different types of copolymers. In the case where the polyolefin A is a copolymer, it may be a random copolymer or a block copolymer.

The α-olefin includes, for example, 1-butene, 1-pentene, 1-hexene, 1-heptene, 1-octene, 4-methyl-1-pentene, 4-methyl-1-hexene, etc. Above all, 1-butene, 1-hexene, 1-octene and 4-methyl-1-pentene are preferred as the α-olefin. The other ethylenic unsaturated monomer includes, for example, vinyl acetate, acrylic acid, acrylates, methacrylic acid, methacrylates, vinyl alcohol, etc. One alone or two or more different types of the above α-olefins and ethylenic unsaturated monomers may be used here either singly or as combined.

In particular, the polyolefin A is especially preferably a polypropylene-based resin such as polypropylene (propylene homopolymer), copolymer of ethylene and propylene, copolymer of propylene and other α-olefin or the like, from the viewpoint of the heat resistance and the flexibility thereof.

Not specifically defined, the density of the polyolefin A is preferably from 0.84 to 0.89 g/cm³, more preferably from 0.85 to 0.89 g/cm³. The density of more than 0.89 g/cm³ would impair the flexibility and the pressure-sensitive slight adhesiveness of the resin. On the other hand, the density of less than 0.84 g/cm³ would worsen the moldability and the heat resistance of the resin.

As commercial products of the polyolefin A, for example, there are mentioned a trade name “Tafthren H5002” (by Sumitomo Chemical, polypropylene-based elastomer, crystal melting energy: 11.3 J/g, density: 0.86 g/cm³), a trade name “Notio PN20300” (by Mitsui Chemical, polypropylene-based elastomer, crystal melting energy: 23.4 J/g, density: 0.868 g/cm³), a trade name “Licocene PP1502” (by Clariant, polypropylene-based wax, crystal melting energy: 26.0 J/g, density: 0.87 g/cm³), a trade name “Licocene PP 1602” (by Clariant, polypropylene-based wax, crystal melting energy: 26.9 J/g, density: 0.87 g/cm³), a trade name “Licocene PP2602” (by Clariant, polypropylene-based wax, crystal melting energy: 39.8 J/g, density: 0.89 g/cm³).

In the case where the specific polyolefin-based pressure-sensitive adhesive layer contains the polyolefin A, the proportion of the polyolefin A is, though not specifically defined, preferably 70% by weight or more (for example, from 70 to 100% by weight) with respect to the total polyolefin amount (100% by weight) in the specific polyolefin-based pressure-sensitive adhesive layer, more preferably 75% by weight (for example, from 75 to 100% by weight). When the proportion of the polyolefin A is less than 70% by weight, then the polyolefin-based pressure-sensitive adhesive layer could hardly have good flexibility and pressure-sensitive slight adhesiveness while having sufficient repeelability.

In case where the specific polyolefin-based pressure-sensitive adhesive layer contains the polyolefin A, it is desirable that the specific polyolefin-based pressure-sensitive adhesive layer further contains a polyolefin having a crystal melting energy of 50 J/g or more (polyolefin B) along with the polyolefin A. When the specific polyolefin-based pressure-sensitive adhesive layer contains the polyolefin B along with the polyolefin A, then the layer could readily exhibit heat resistance in addition to the above-mentioned characteristics such as repeelability, etc. In this application, the “polyolefin having a crystal melting energy of 50 J/g or more” may be referred to as “polyolefin B”. The polyolefin B is a so-called crystalline polyolefin and contains a large number of crystal structures. The specific polyolefin-based pressure-sensitive adhesive layer may contain one polyolefin B alone or two or more different types of polyolefins B.

In other words, the specific polyolefin-based pressure-sensitive adhesive layer is preferably a polyolefin-based pressure-sensitive adhesive layer containing the polyolefin A and the polyolefin B.

Not specifically defined, the polyolefin B includes, for example, low-density polyethylene, middle-density polyethylene, high-density polyethylene, linear low-density polyethylene, polypropylene, copolymer of ethylene and propylene, copolymer of ethylene and other α-olefin, copolymer of propylene and other α-olefin, copolymer of ethylene, propylene and other α-olefin, copolymer of ethylene and other ethylenic unsaturated monomer, etc. The polyolefin B may be a mixture of a homopolymer and a copolymer, or a mixture of different types of copolymers. In the case where the polyolefin B is a copolymer, it may be a random copolymer or a block copolymer.

The α-olefin includes, for example, 1-butene, 1-pentene, 1-hexene, 1-heptene, 1-octene, 4-methyl-1-pentene, 4-methyl-1-hexene, etc. Above all, 1-butene, 1-hexene, 1-octene and 4-methyl-1-pentene are preferred as the α-olefin. The other ethylenic unsaturated monomer includes, for example, vinyl acetate, acrylic acid, acrylates, methacrylic acid, methacrylates, vinyl alcohol, etc. One alone or two or more different types of the above α-olefins and ethylenic unsaturated monomers may be used here either singly or as combined.

In particular, the polyolefin B is especially preferably a polypropylene-based resin such as polypropylene (propylene homopolymer), copolymer of ethylene and propylene, copolymer of propylene and other α-olefin or the like, from the viewpoint of the heat resistance thereof.

Not specifically defined, the density of the polyolefin B is preferably from 0.90 to 0.91 g/cm³. When the density is less than 0.90 g/cm³, then the heat resistance of the polyolefin would be poor. On the other hand, the polyolefin B having a density of more than 0.91 g/cm³ is hardly available.

As commercial products of the polyolefin B, for example, there are mentioned a trade name “Hiwax NP055” (by Mitsui Chemical, polypropylene-based wax, crystal melting energy: 89.1 J/g, density: 0.90 g/cm³), etc.

In the case where the specific polyolefin-based pressure-sensitive adhesive layer contains the polyolefin A and the polyolefin B, the proportion of the polyolefin B is, though not specifically defined, preferably from 3 to 30% by weight with respect to the total polyolefin amount (100% by weight) in the specific polyolefin-based pressure-sensitive adhesive layer, more preferably from 4 to 28% by weight, even more preferably from 5 to 25% by weight. When the proportion of the polyolefin B is more than 30% by weight, then the polyolefin-based pressure-sensitive adhesive layer would be too hard whereby the flexibility and the pressure-sensitive slight adhesiveness of the foam laminate would be worsened and the dust-proofness (especially dynamic dust-proofness) of the foam laminate would also be worsened, and in addition, the polyolefin-based pressure-sensitive adhesive layer would be brittle. On the other hand, when the proportion of the polyolefin B is less than 3% by weight, then the polyolefin-based pressure-sensitive adhesive layer could not secure sufficient heat resistance.

Specifically, it is desirable that the specific polyolefin-based pressure-sensitive adhesive layer has a peelability from an acrylic plate of from 0.1 N/20 mm to 2.5 N/20 mm and contains the polyolefin A and the polyolefin B, in which the proportion of the polyolefin B is from 3 to 30% by weight with respect to the total polyolefin amount (100% by weight) in the specific polyolefin-based pressure-sensitive adhesive layer.

The specific polyolefin-based pressure-sensitive adhesive layer may contain additives such as a tackifier (tackifying resin), an antioxidant, an antiaging agent, a plasticizer, a colorant, a filler, other resins (resins except polyolefin A and polyolefin B), etc., within a range not impairing the advantageous effects of the invention. One alone or two or more such additives may be used in the layer either singly or as combined.

Especially preferably, the specific polyolefin-based pressure-sensitive adhesive layer contains a tackifier (tackifying resin). When containing a tackifier, the pressure-sensitive adhesive force of the pressure-sensitive adhesive layer can be thereby increased, and for example, the sliding resistance and the dust-proofness of the foam laminate of the invention can be thereby improved. One alone or two or more different types of tackifiers may be in the layer.

The tackifier is a resin having a softening point (according to JIS K 2207) of from 70 to 180° C., more preferably a resin having a softening point of from 80 to 160° C., even more preferably a resin having a softening point of from 90 to 150° C. When the softening point is too high, then the repeelability of the foam laminate may lower and the resin flexibility and the pressure-sensitive slight adhesiveness thereof may worsen. On the other hand, when the softening point is too low, then the heat resistance of the foam laminate may lower.

Not specifically defined, the tackifier may be any one of which the softening point falls within the above-mentioned range, and includes, for example, aliphatic petroleum resin, completely hydrogenated aliphatic petroleum resin, partially hydrogenated aliphatic petroleum resin, aromatic petroleum resin, completely hydrogenated aromatic petroleum resin, partially hydrogenated aromatic petroleum resin, etc.

The content of the tackifier in the specific polyolefin-based pressure-sensitive adhesive layer is not specifically defined. However, when the content of the tackifier is too much, then the layer would lose repeelability; but on the other hand, when the content of the tackifier is too small, then the tackifier could not attain the intended effect (for example, further improving the dust-proofness of the layer). Accordingly, the content of the tackifier in the polyolefin-based pressure-sensitive adhesive layer is preferably 25 parts by weight or less (for example, from 1 to 25 parts by weight) with respect to 100 parts by weight of the polyolefin in the layer (in the case where the layer contains the polyolefin A and the polyolefin B, the content is relative to the total amount, 100 parts by weight of the polyolefin A and the polyolefin B), more preferably 20 parts by weight or less (for example, from 3 to 20 parts by weight).

The foam laminate of the invention has the above-mentioned specific pressure-sensitive adhesive layer (especially the above-mentioned polyolefin-based pressure-sensitive adhesive layer) on at least one side of a foam layer, in which the thickness of the specific pressure-sensitive adhesive layer (especially the thickness of the specific polyolefin-based pressure-sensitive adhesive layer) is, though not specifically defined, preferably from 1 to 50 μm, more preferably from 2 to 40 μm. When the thickness is less than 1 μm, then the layer could not secure sufficient adhesiveness; but on the other hand, when the thickness is more than 50 μm, then the flexibility of the foam laminate would lower. The specific pressure-sensitive adhesive layer may have a single-layer structure or a laminate structure.

### (Foam Layer)

The foam laminate of the invention has a foam layer. Accordingly, the foam laminate of the invention is excellent in flexibility and impact absorbability. The foam layer is formed by foaming and shaping a resin composition. The resin composition is a composition to be obtained by mixing a resin as a raw material and additives optionally added thereto.

The foam layer has a cell structure. Not specifically defined, the cell structure may be any of a closed cell structure, a semi-interconnected semi-closed cell structure (in which a closed cell structure and an interconnected cell structure are mixed, and the ration thereof is not specifically defined), or an interconnected cell structure. In particular, the foam layer preferably has a cell structure of a closed cell structure or a semi-interconnected semi-closed cell structure from the viewpoint of providing better flexibility. The semi-interconnected semi-closed cell structure is, for example, a cell structure in which the closed cell structure moiety accounts for 40% (by volume) or less (preferably 30% (by volume) or less) of the cell structure.

The density (apparent density) of the foam layer may be suitably defined depending on the intended use, but is preferably from 0.02 to 0.20 g/cm³, more preferably from 0.03 to 0.17 g/cm³, even more preferably from 0.04 to 0.15 g/cm³. When the density of the foam layer is more than 0.20 g/cm³, then the foaming of the layer would be insufficient and the flexibility thereof would lower. On the other hand, when less than 0.02 g/cm³, it is undesirable since the strength of the foam layer would greatly lower.

The density of the foam layer may be determined as follows: The foam layer is punched out with a punching blade of 40 mm×40 mm, and the dimension (length, width) of the punched-out sample is measured. Using a 1/100 dial gauge of which the measuring terminal has a diameter (φ) of 20 mm, the thickness of the sample is measured. From the dimension of the sample and the thickness of the sample, the volume of the sample is calculated. Next, the weight of the sample is measured on a scale balance of which the measurement limit is 0.01 g. From the volume of the sample and the weight of the sample, the density (g/cm³) of the foam layer is calculated.

Not specifically defined, the thickness of the foam layer is, for example, preferably from 0.1 mm to 5 mm, more preferably from 0.2 mm to 3 mm, from the viewpoint of the dust-proofness and the impact absorbability thereof and from the viewpoint of applicability of the foam laminate to thin, small-sized and narrow-shaped electronic or electric devices.

The foam layer is formed of a resin. Not specifically defined, the resin constituting the foam layer may be any and every resin that is thermoplastic and can be impregnated with vapor (for gases to form cells), but is preferably a thermoplastic resin. The foam layer may be formed of only one resin, or may be formed of two or more different types of resins.

Examples of the thermoplastic resin include polyolefin-based resins such as low-density polyethylene, middle-density polyethylene, high-density polyethylene, linear low-density polyethylene, polypropylene, copolymer of ethylene and propylene, copolymer of ethylene, propylene and any other α-olefin (for example, butene-1, pentene-1, hexene-1, 4-methyl-pentene-1, etc.), copolymer of ethylene and any other ethylenic unsaturated monomer (for example, vinyl acetate, acrylic acid, acrylates, methacrylic acid, methacrylates, polyvinyl alcohol, etc.), etc.; styrenic resins such as polystyrene, acrylonitrile-butadiene-styrene copolymer (ABS resin), etc.; polyamide resins such as 6-nylon, 66-nylon, 12-nylon, etc.; polyamideimides; polyurethanes; polyimides; polyetherimides; acrylic resins such as polymethyl methacrylate, etc.; polyvinyl chloride; polyvinyl fluoride; alkenyl aromatic resins; polyester resins such as polyethylene terephthalate, polybutylene terephthalate, etc.; polycarbonates such as bisphenol A-type polycarbonate, etc.; polyacetals; polyphenylene sulfides, etc. In the case where the thermoplastic resin is a copolymer, it may be a copolymer of any form of a random copolymer or a block copolymer. One alone or two or more different types of thermoplastic resins may be used either singly or as combined to form the layer.

Of the above-mentioned thermoplastic resins, preferred are the above-mentioned polyolefin-based resins. The polyolefin-based resins are preferably resins of a type having a broad molecular weight and having a shoulder on the high-molecular weight side, resins of a slightly-crosslinked type (resins of a type crosslinked slightly therein), or resins of a long-chain branched type.

Further, the thermoplastic resin includes a thermoplastic elastomer (for example, thermoplastic elastomers mentioned below). In the case where the resin constituting the foam layer contains a thermoplastic elastomer, then the flexibility and the shape followability of the foam layer can be greatly bettered since the glass transition temperature of the thermoplastic elastomer is not higher than room temperature (for example, 20° C. or less).

Not specifically defined, the thermoplastic elastomer includes various types of thermoplastic elastomers, for example, natural or synthetic rubbers such as natural rubber, polyisobutylene, polyisoprene, chloroprene rubber, butyl rubber, nitrile butyl rubber, etc.; olefinic elastomers such as ethylene-propylene copolymer, ethylene-propylene-diene copolymer, ethylene-vinyl acetate copolymer, polybutene, chloropolyethylene, etc.; styrenic elastomers such as styrene-butadiene-styrene copolymer, styrene-isoprene-styrene copolymer, and their hydrogenated products; polyester elastomers; polyamide elastomers; polyurethane elastomers, etc. One alone or two or more different types of thermoplastic elastomers may be used here either singly or as combined.

Of the above-mentioned thermoplastic elastomers, especially preferred are the above-mentioned olefin-based elastomers. The olefin-based elastomers have a structure in which an olefin-based resin component such as polyethylene or polypropylene and an olefin-based rubber component such as ethylene-propylene rubber or an ethylene-propylene-diene rubber are in microscopic phase separation. The olefin-based elastomers may also be in a type where the constitutive components are physically dispersed or in a type where the components are dynamically heat-treated in the presence of a crosslinking agent. The olefin-based elastomers have good compatibility with the polyolefin-based resins that are exemplified at the above-mentioned thermoplastic resin.

In particular, the foam layer is preferably formed of the above-mentioned thermoplastic resin (the above-mentioned thermoplastic resin except the above-mentioned thermoplastic elastomer) and the above-mentioned thermoplastic elastomer. The ratio of the thermoplastic resin (the thermoplastic resin except the thermoplastic elastomer) and the thermoplastic elastomer is not specifically defined. However, when the proportion of the thermoplastic elastomer is too small, then the cushionability of the foam layer may lower; but on the other hand, when the proportion of the thermoplastic elastomer is too large, then there may occur gas leakage in cell structure formation and the foam layer could not have a highly-foamed cell structure. Consequently, for example, in the case where the foam layer is formed of the above-mentioned polyolefin-based resin (the above-mentioned polyolefin-based resin except the above-mentioned olefin-based elastomer) such as polypropylene or the like and the above-mentioned olefin-based elastomer, the ratio (by weight) of the polyolefin-based resin to the olefin-based elastomer is, as a ratio of former/latter, preferably from 1/99 to 99/1, more preferably from 10/90 to 90/10, even more preferably from 20/80 to 80/20.

In the invention, the melt flow rate (MFR) of the resin composition constituting the foam layer is preferably from 0.1 to 30 g/10 min, more preferably from 0.2 to 15 g/10 min, even more preferably from 0.3 to 10 g/10 min. When MFR is higher than 30 g/10 min, then the resin composition is soft and there may occur gas leakage in foaming; but when lower than 0.1 g/10 min, then the resin composition would be too hard to be extruded out. Unless otherwise specifically indicated here, MFR is a value measured at “230° C. and 98 N”.

If desired, the foam layer may contain various additives. Not specifically defined, the additives include, for example, a cell nucleator (particles to be mentioned below, etc.), a crystal nucleator, a plasticizer, a lubricant, a colorant (pigment, dye, etc.), an UV absorbent, an antioxidant, an aging inhibitor, a filler, a reinforcing agent, an antistatic agent, a surfactant, a tension improver, a shrinkage inhibitor, a flowability improver, clay, a vulcanizing agent, a surface-treating agent, a flame retardant (powdery flame retardant, other various types of flame retardants except powder one, etc.), etc. The amount of the additive may be suitably selected within a range not impairing the foam formation, etc.

Preferably, the foam layer contains particles. Particles can exhibit the function as a cell nucleator (a foam nucleator) in foaming and shaping the resin composition, and therefore, when containing particles, the resin composition can form a foam layer in which the cell structure can be in a good foaming state. The particles include, for example, talc, mica, alumina, zeolite, calcium carbonate, magnesium carbonate, barium sulfate, zinc oxide, titanium oxide, aluminium hydroxide, magnesium hydroxide, mica, clay such as montmorillonite, as well as carbon particles, glass fibers, carbon tubes, etc. One alone or two or more different types of such particles can be used here either singly or as combined.

Especially preferably, the particles have an average particle size (particle diameter) of from 0.1 to 20 μm. When the average particle size of the particles is less than 0.1 μm, the particles could not sufficiently function as a nucleator; and on the other hand, when the particle size is more than 20 μm, the particles would bring about a risk of gas leakage during foaming and shaping.

The content of the particles in the foam layer is not specifically defined. For example, it is desirable that the content thereof is from 0.1 to 150 parts by weight relative to 100 parts by weight of the total resin amount in the resin composition, more preferably from 1 to 130 parts by weight, even more preferably from 2 to 50 parts by weight. When the content is less than 0.1 parts by weight, then the particles could not sufficiently function as a cell nucleator during foaming and shaping of the resin composition and therefore the foam layer could not have a uniform cell structure therein; but on the other hand, when more than 150 parts by weight, then the viscosity of the resin composition would greatly increase, therefore bringing about a risk of gas leakage during foaming and shaping, thereby impairing the foamability of the composition, and the resin composition could not form a highly-foamed cell structure.

Also preferably, the foam layer contains a flame retardant (powdery flame retardant, other various types of flame retardants except powdery one). The foam laminate of the invention is often used in applications in which flame retardation is indispensable, such as electric or electronic devices, etc. However, the foam layer is formed of a thermoplastic resin and is combustible, and therefore, it is desirable that the foam layer contains a flame retardant.

The powdery flame retardant is preferably an inorganic flame retardant. The inorganic flame retardant includes, for example, bromine-containing flame retardants, chlorine-containing flame retardants, phosphorus-containing flame retardants, antimony-containing flame retardants, non-halogen/non-antimony inorganic flame retardants, etc. Here, chlorine-containing flame retardants and bromine-containing flame retardants have a problem that, during burning, they generate a gaseous component harmful to human bodies and corrosive to instruments; and phosphorus-containing flame retardants and antimony-containing flame retardants have a problem of harmfulness and explosiveness. Consequently, non-halogen/non-antimony inorganic flame retardants are preferred for the inorganic flame retardant for use herein. Non-halogen/non-antimony inorganic flame retardants include, for example, aluminium hydroxide, magnesium hydroxide, as well as metal hydrate compounds such as magnesium oxide/nickel oxide hydrates, magnesium oxide/zinc oxide hydrates, etc. The metal hydrate compound may be surface-treated. One alone or two or more different types of powdery flame retardants may be used here either singly or as combined.

The content of the flame retardant in the foam layer is not specifically defined. However, when the amount is too small, then the flame retardation effect could not be attained; but on the contrary, when too large, a highly-foamed cell structure could not be formed. For example, the content of the powdery flame retardant in the resin composition is preferably from 5 to 130 parts by weight relative to 100 parts by weight of the total resin amount therein, more preferably from 10 to 120 parts by weight.

The powdery flame retardant may function as a cell nucleator. In such a case, it is desirable that the foam layer contains the powdery flame retardant alone capable of functioning as a cell nucleator, rather than containing both a cell nucleator and a flame retardant, from the viewpoint of satisfying both sufficient flame retardation and highly-foamed cell structure.

The foam layer may be formed by foaming and shaping the resin composition that is prepared by mixing a resin as a raw material and additives optionally added thereto. The foaming method for foaming and shaping the resin composition is not specifically defined. For example, employable here are a physical method (where a low-boiling-point liquid (foaming agent) is dispersed in the resin composition and then the composition is heated to vaporize the foaming agent to form cells), and a chemical method (where cells are formed by the gas generated through thermal decomposition of the compound (foaming agent) added to the resin composition).

As the foaming method to be employed in foaming and shaping the resin composition, preferred is the physical foaming method, and in particular, from the viewpoint that a cell structure having a small cell diameter and a high cell density can be formed with ease, more preferred is the physical foaming method that uses a high-pressure gas as the foaming agent.

More preferably, the gas serving as the foaming agent is an inert gas that is inert to the resin in the resin composition. Specifically, it is desirable that the foam layer is formed by foaming the resin composition according to the physical foaming method that uses a high-pressure inert gas as the foaming agent. Not specifically defined, the inert gas may be any one inert to the resin constituting the foam layer and capable of being impregnated thereinto. For example, there are mentioned carbon dioxide, nitrogen gas, air, etc. In particular, carbon dioxide is preferred as the inert gas from the viewpoint that it can much be impregnated into the resin and its impregnation speed is high. The inert gas may also be a mixed gas.

From the viewpoint of increasing the impregnation speed, it is desirable that the high-pressure gas (especially inert gas, more preferably carbon dioxide) is in a supercritical state. In a supercritical state, the solubility of the gas in the resin increases and a high-concentration gas can be mixed in the resin. In rapid pressure drop after gas impregnation, the gas can be impregnated into the resin at such a high concentration as mentioned above, and therefore many cell nuclei can be formed and, as a result, the density of the cells to be formed after growth of the cell nuclei can be large on the same porosity level, and for these reasons, microcells can be formed under the condition. The critical temperature of carbon dioxide is 31° C., and the critical pressure thereof is 7.4 MPa.

As the physical foaming method that uses a high-pressure gas as the foaming agent, preferred is a method where a high-pressure gas has is impregnated into the resin composition and thereafter the composition is foamed through a step of reducing the pressure of the system. Concretely, more preferred is a method where a high-pressure gas is impregnated into an unfoamed shaped product of the resin composition and then the system is depressurized to foam the composition, or a method where a gas under pressure is impregnated into the molten resin composition and the system is depressurized to shape and foam the composition.

Specifically, the foam layer may be formed according to a batch process in which the resin composition is previously shaped into a sheet or the like to give an unfoamed resin shaped product (unfoamed shaped product), and a high-pressure gas is impregnated into the unfoamed resin shaped product and the pressure is released for foaming; or may be formed according to a continuous process in which the resin composition is kneaded under pressure along with a high-pressure gas and then the pressure is released simultaneously with shaping the composition to thereby attain shaping and foaming of the composition at a time.

The method of forming the unfoamed resin shaped product in the above-mentioned batch process is not specifically defined. For example, there are mentioned a method of shaping the resin composition by the use of an extruder such as a single-screw extruder, a twin-screw extruder, etc.; a method comprising uniformly kneading the resin composition by the use of a kneading apparatus equipped with a roller, a cum, a kneader, a Banbury-type or the like blade, followed by pressing it into a predetermined thickness by the use of a hot plate press or the like; a method of molding the resin composition by the use of an injection molding machine, etc. Not specifically defined, the shape of the unfoamed resin shaped product may be, for example, a sheet, a roll, a plate, etc. According to the above-mentioned batch process, the resin composition may be shaped according to a suitable method of giving an unfoamed resin shaped product having a desired shape and a desired thickness.

According to the batch process, cells are formed through a gas impregnation step where the unfoamed resin shaped product is put into a pressure container, and then a high-pressure gas is injected (introduced) thereinto, and a depressurizing step where the pressure is released (generally to atmospheric pressure) at the time when a high-pressure gas has sufficiently impregnated into the shaped product to thereby generate cell nuclei in the resin.

On the other hand, according to the continuous process, the resin composition is foamed and shaped through a step where a high-pressure gas is injected (introduced) into the resin composition while the composition is kneaded by an extruder (for example, a single-screw extruder, a twin-screw extruder, etc.) or an injection-molding machine so that the high-pressure gas is fully impregnated into the resin composition, and a shaping and depressurizing step where the resin composition is extruded out through the die arranged at the top of an extruder or the like to thereby release the pressure (generally to atmospheric pressure), and is thus shaped and foamed simultaneously.

If desired, the batch process or the continuous process may include a heating step of growing the cell nuclei by heating. Not in such a heating step, the cell nuclei may be grown at room temperature in the process. Further, after the cells have been grown, if desired, they may be rapidly cooled by cold water or the like, to thereby fix the shape thereof. High-pressure gas introduction may be carried out continuously or discontinuously. The heating method in growing the cell nuclei is not specifically defined. For example, there may be mentioned known or conventional methods using a water bath, an oil bath, a hot roll, a hot air oven, far-IR rays, near-IR rays, microwaves, etc.

In the batch process or the continuous process, the gas mixing amount is not specifically defined. For example, the amount may be from 2 to 10% by weight with respect to the total resin amount in the resin composition.

In the gas impregnation step in the batch process or in the kneading impregnation step in the continuous process, the pressure in gas impregnation may be suitably selected in consideration of the type and the operability of the gas. For example, in the case where an inert gas, especially carbon dioxide is used as the gas, the pressure is preferably 6 MPa or more (for example, from 6 to 100 MPa), more preferably 8 MPa or more (for example, from 8 to 100 MPa). When the gas pressure is lower than 6 MPa, then the cells grow greatly in foaming so that the cell diameter becomes too large, and for example, there may occur some inconvenience of dust-proofness reduction, and therefore such a low pressure is undesirable. This is because, when the pressure is low, the gas impregnation amount is relatively low as compared with that under high pressure, and therefore the cell nucleation rate lowers and the number of cell nuclei to be formed reduces, or that is, the gas amount per one cell inversely increases and therefore the cell diameter becomes enormously large. On the other hand, in the pressure region lower than 6 MPa, the cell diameter and the cell density may greatly change even when the gas impregnation pressure is changed only a little, and therefore the cell diameter and the cell density are often difficult to control.

In the gas impregnation step in the batch process or in the kneading impregnation step in the continuous process, the temperature in gas impregnation (gas impregnation temperature) may vary depending on the type of the gas and the resin to be used, and can be selected within a broad range. When the operability is taken into consideration, the temperature is preferably from 10 to 350° C. More concretely, the gas impregnation temperature in the batch process is preferably from 10 to 250° C., more preferably from 40 to 240° C., even more preferably from 60 to 230° C. In the continuous process, the gas impregnation temperature is preferably from 60 to 350° C., more preferably from 100 to 320° C., even more preferably from 150 to 300° C. In case where carbon dioxide is used as the high-pressure gas, the temperature in gas impregnation (gas impregnation temperature) is preferably 32° C. or more (especially 40° C. or more) for securing the supercritical state thereof.

Further, in the batch process or the continuous process, the depressurization rate in the depressurization step is not specifically defined. For forming uniform microcells, the rate is preferably from 5 to 300 MPa/sec. The heating temperature in the heating step is, for example, preferably from 40 to 250° C., more preferably from 60 to 250° C.

The physical foaming method that uses a high-pressure gas as the foaming agent in foaming and shaping the resin composition has an advantage in that a highly-foamed cell structure can be formed and the thickness of the foam layer can be larger. For example, according to the method, there can be formed a foam layer having a thickness of from 0.50 to 5.00 mm.

Not specifically defined, the thickness of the foam layer is preferably from 0.1 mm to 5 mm, more preferably from 0.2 mm to 3 mm. When the thickness is less than 0.1 mm, then there may occur a risk in that the dust-proofness of the foam laminate may lower and the cushionability thereof may also lower. On the other hand, when the thickness is more than 5 mm, then the foam laminate could hardly be applied to electronic or electric devices having thin, small-sized and narrow shapes. The thickness of the foam layer may be controlled by previously forming a foam layer having a predetermined thickness and then slicing the layer into thinner layers each having a desired thickness.

In the physical foaming method that uses a high-pressure gas as the foaming agent, when a thick foam layer is formed, it is desirable that the relative density [density after foaming/density before foaming (for example, the density of the resin composition or the density of the unfoamed shaped product)] is from 0.02 to 0.30, more preferably from 0.03 to 0.25. When the relative density is more than 0.30, then the foaming would be insufficient and the flexibility of the foam layer may lower. On the other hand, when the relative density is less than 0.02, then the strength of the foam layer would significantly lower, which is undesirable.

The cell structure, the density and the relative density of the foam layer can be controlled by selecting the foaming method and the foaming condition (for example, the type and the amount of the foaming agent, the temperature, the pressure and the time in foaming) in forming and shaping the resin composition, in accordance with the type of the resin constituting the foam layer. For example, a foam layer composed of a polyolefin-based resin and having a density (apparent density) of from 0.02 to 0.20 g/cm³ can be readily formed according to the above-mentioned physical foaming method that uses a high-pressure gas as the foaming agent, in which a gas (preferably an inert gas, more preferably carbon dioxide) serving as the foaming agent is impregnated into the resin composition in a temperature atmosphere of from 150° C. to 190° C. and under a pressure of from 10 MPa to 30 MPa.

### (Other Layers)

The foam laminate of the invention may have any other layer in addition to the specific polyolefin-based pressure-sensitive adhesive layer and the foam layer mentioned above. The other layer includes, for example, an interlayer to be arranged between the foam layer and the specific polyolefin-based pressure-sensitive adhesive layer (for example, an undercoat layer for improving the adhesiveness between the two layers, a substrate layer serving as a core material (for example, a film layer, a nonwoven fabric layer, etc.)), and any other pressure-sensitive adhesive layer than the above-mentioned specific polyolefin-based pressure-sensitive adhesive layer (other pressure-sensitive adhesive layer).

The method for producing the foam laminate of the invention is not specifically defined. For example, the specific polyolefin-based pressure-sensitive adhesive layer may be provided on one side or both sides of a foam layer to form the foam laminate.

For example, the foam laminate having the specific olefin-based pressure-sensitive adhesive layer on at least one side of a foam layer can be produced by applying a polyolefin-based pressure-sensitive adhesive composition onto at least one side of a foam layer and then curing it to form a polyolefin-based pressure-sensitive adhesive layer thereon. The polyolefin-based pressure-sensitive adhesive composition is a composition to form the specific polyolefin-based pressure-sensitive adhesive layer, and contains a composition to form a pressure-sensitive adhesive agent. The specific polyolefin-based pressure-sensitive adhesive layer may be prepared by mixing raw materials of polyolefins such as polyolefin A, polyolefin B and others, and additives optionally added thereto. In mixing the raw materials, heat may be given thereto.

In coating with the polyolefin-based pressure-sensitive adhesive composition, it is desirable that the polyolefin-based pressure-sensitive adhesive composition is in a molten state by heating, from the viewpoint of the workability. Not specifically defined, the melt viscosity of the polyolefin-based pressure-sensitive adhesive composition is, for example, preferably from 1 to 30 Pa·s as the melt viscosity thereof at 200° C., more preferably from 2 to 20 Pa·s, from the viewpoint of the accurate coatability of accurately applying the composition onto the foam layer and forming the intended pressure-sensitive adhesive layer thereon. When the melt viscosity is more than 30 Pa·s, then the viscosity is high and uniform coating would be difficult; but on the other hand, when less than 1 Pa·s, then the viscosity is too low and the composition would flow during coating and therefore the coating layer could hardly have a constant shape. The melt viscosity of the polyolefin-based pressure-sensitive adhesive composition is the melt viscosity of the polyolefin-based pressure-sensitive adhesive layer.

Specifically, the above-mentioned, specific polyolefin-based pressure-sensitive adhesive layer is preferably a hot-melt pressure-sensitive adhesive layer (that is, a pressure-sensitive adhesive layer which is formed by heating and melting a hot-melt type, pressure-sensitive adhesive composition that is solid at room temperature and applying the resulting melt to a foam layer and then cooling it thereon), and is especially preferably a hot-melt pressure-sensitive adhesive layer having a melt viscosity at 200° C. of from 1 to 30 Pa·s.

Not specifically defined, the thickness of the foam laminate of the invention is preferably from 0.1 mm to 5 mm, more preferably from 0.2 mm to 3 mm, from the viewpoint of the applicability thereof to thin, small-sized and narrow-shaped electronic or electric devices.

Preferably, the foam laminate of the invention has good heat resistance, when evaluated according to an evaluation method for heat resistance mentioned below. When the heat resistance evaluated as follows is not good, then the pressure-sensitive adhesive layer in the foam laminate incorporated inside an electric/electronic device may dissolve out of the foam laminate during use of the device, thereby often bringing about some failures of, for example, a breakdown of the electric/electronic device or some negative influence on the visibility of the display part of the electric/electronic device.

### Evaluation Method for Heat Resistance

A sample compressed in the thickness direction so that its thickness could be 50% of the thickness thereof before compression is stored in an atmosphere at a temperature of 60° C. for 72 hours, and visually checked as to whether or not the pressure-sensitive adhesive layer has dissolved out of the foam laminate. The samples where the pressure-sensitive adhesive layer did not dissolve out are evaluated as good; while the samples where the pressure-sensitive adhesive layer dissolved out are evaluated as not good.

The foam laminate of the invention has the specific polyolefin-based pressure-sensitive adhesive layer and therefore has good repeelability. In this application, “repeelability” means a property that, when the foam laminate adhered to an adherend in such a manner that the specific polyolefin-based pressure-sensitive adhesive layer thereof is kept in contact with the adherend is peeled away from the adherend, it can be readily removed with no damage to the foam layer, for example with no breakage of the foam layer, and with no stain left on the adherend. In addition, as having excellent repeelability, the foam laminate of the invention promotes recycling of structural members and saving natural resources.

When the foam laminate of the invention has, as the pressure-sensitive adhesive layer therein, the specific polyolefin-based pressure-sensitive adhesive layer containing a polyolefin A, then the foam laminate is excellent not only in repeelability but also in flexibility and the pressure-sensitive slight adhesiveness. Accordingly, when the foam laminate of the invention has the specific polyolefin-based pressure-sensitive adhesive layer containing a polyolefin A, then it is excellent in dust-proofness, especially in dynamic dust-proofness (dust-proofness in dynamic environments).

When the foam laminate of the invention has, as the pressure-sensitive adhesive layer therein, the specific polyolefin-based pressure-sensitive adhesive layer containing a polyolefin A and a polyolefin B, then the foam laminate exhibits heat resistance in addition to the above.

When the foam laminate of the invention has good heat resistance, then its dimensional stability (the property that the dimensional change is small in a change of temperature and time) is excellent. The foam laminate of the invention is often incorporated inside an electric/electronic device, and during use of the electric/electronic device, the atmosphere inside the electric/electronic device would be at a temperature of from 60 to 100° C. In such a condition, when the heat resistance of the foam laminate is good, then there may occur neither lowering nor degradation of the performance of the device in the temperature atmosphere.

When the foam laminate of the invention has, as the pressure-sensitive adhesive layer therein, the specific polyolefin-based pressure-sensitive adhesive layer that contains a polyolefin prepared through polymerization with a metallocene catalyst, then the foam laminate exhibits contamination resistance in addition to the above. When the foam laminate of the invention has contamination resistance, it brings about some advantages. For example, in disjointing an electric or electronic device with the foam laminate incorporated therein, or in reworking during incorporating the foam laminate into an electric or electronic device, when the foam laminate is removed from the resin face or the metal face of the device housing, or from the glass face of the image display part, the resin face or the metal face of the device housing and the glass face of the image display part are protected from being contaminated. Consequently, when the foam laminate of the invention is resistant to contamination, then it is advantageous in reworking during incorporating the foam laminate into an electric or electronic device and is also advantageous in recycling the parts, the members, the housings and others constituting electric or electronic devices.

The foam laminate of the invention is favorably used, for example, for portable telephones, portable terminals, digital cameras, video movies, personal computers, liquid-crystal TVs, other home electric appliances, etc. More specifically, the foam laminate of the invention is favorably used in an electric or electronic device as a gasket for fitting (mounting) various members or parts constituting the electric or electronic device in a predetermined site therein.

The members or the parts constituting electric or electronic devices that may be fitted (mounted) by the use of the foam laminate of the invention are not specifically limited. For example, there are mentioned image display members (especially small-sized image display members) to be mounted on image display devices such as liquid-crystal displays, electroluminescence displays, plasma displays, etc., as well as optical members or optical parts such as cameras, lenses (especially small-sized cameras and lenses) and others to be mounted on mobile communication devices such as so-called “mobile phones”, “mobile information terminals”, etc.

### (Electric or Electronic Devices)

Using the foam laminate of the invention, there can be provided electric or electronic devices containing a foam laminate for electric or electronic devices. The electric or electronic devices are so designed that the members or the parts of the electric or electronic device are fitted (mounted) in predetermined sites via the foam laminate for electric or electronic devices.

The electric or electronic devices include, for example, electric or electronic devices as so designed that an image display device such as a liquid-crystal display, an electroluminescence display, a plasma display or the like as an optical member or part (especially an image display device with a small-sized display member mounted thereon as an optical member) or a camera or a lens (especially a small-sized camera or lens) is mounted via the foam laminate for electric or electronic devices (for example, mobile telecommunications such as so-called “mobile phones”, “mobile information terminals”, etc.). These electric or electronic devices may be thinner than conventional ones, and the thickness and the shape thereof are not specifically defined.

### EXAMPLES

The invention is described in more detail with reference to the following Examples; however, the invention is not limited by these Examples.

### Production Example 1 for Foam Layer

50 parts by weight of polypropylene (melt flow rate (MFR): 0.35 g/10 min), 55 parts by weight of polyolefin-based elastomer (melt flow rate (MFR): 6 g/10 min, JIS A hardness: 79°), 6 parts by weight of carbon black (trade name “Asahi #35”, by Asahi Carbon), and 10 parts by weight of magnesium hydroxide (average particle size: 0.7 μm) were kneaded with a twin-screw extruder manufactured by JSW, at a temperature of 200° C., and then extruded out as strands, then cooled with water and shaped into pellets. The softening point of the pellets was 155° C.

The pellets were put into a single-screw extruder manufactured by JSW, and while kneaded in an atmosphere at 220° C., carbon dioxide gas was injected thereinto under a pressure of 22 MPa (19 MPa after injection). The system was fully saturated with carbon dioxide gas, then cooled to a temperature suitable for foaming, and thereafter extruded out through the die to obtain a foam having a semi-interconnected semi-closed cell structure. The foam has a shape of sheet, the density thereof was 0.05 g/cm³ and the thickness thereof was 2.0 mm.

The foam was sliced to obtain a foam layer (foam layer A) having a thickness of 0.5 mm (sheet-like foam).

### Examples 1 to 9

Materials of each Example shown in Table 1 below was put into Toyo Seiki Seisaku-sho's Labo Plastomill (kneading extruder), and kneaded therein at a rotating number of 30 rpm and at a temperature of 140° C. for 5 minutes, then heated up to 200° C. and further kneaded for 10 minutes to obtain a pressure-sensitive adhesive composition of each Example.

Next, using a coating machine (device name “GPD-300”, manufactured by Yuri Roll Machine) and under the condition of a melting temperature of 200° C., the pressure-sensitive adhesive composition was applied onto the foam layer A in a thickness of 30 μm thereby producing a foam laminate of each Example. The foam laminate has a sheet-like shape and has a layer configuration of foam layer/pressure-sensitive adhesive layer.

### Comparative Example 1

The foam layer obtained in Production Example 1 for Foam Layer was used directly as such.

### Comparative Examples 2, 3 and 4

Materials of each Comparative Example shown in Table 1 below was put into Toyo Seiki Seisaku-sho's Labo Plastomill (kneading extruder), and kneaded therein at a rotating number of 30 rpm and at a temperature of 140° C. for 5 minutes, then heated up to 200° C. and further kneaded for 10 minutes to obtain a pressure-sensitive adhesive composition of each Comparative Example.

Next, using a coating machine (device name “GPD-300”, manufactured by Yuri Roll Machine) and under the condition of a melting temperature of 200° C., the pressure-sensitive adhesive composition was applied onto the foam layer A in a thickness of 30 μm thereby producing a foam laminate of each Comparative Example. The foam laminate has a sheet-like shape and has a layer configuration of foam layer/pressure-sensitive adhesive layer.

TABLE 1

| | | | | | | | | | | | Comparative | | |
|---|---|---|---|---|---|---|---|---|---|---|---|---|---|
| | | Example | | | | | | | | | Example | | |
| | | 1 | 2 | 3 | 4 | 5 | 6 | 7 | 8 | 9 | 2 | 3 | 4 |
| Material | Tafthren H5002 | 25 | 10 | 15 | 15 | 10 | 15 | 15 | | 10 | 10 | 10 | 10 |
| [part by | Licocene PP1602 | | | | 65 | | 80 | 70 | 10 | | | | 70 |
| weight] | Licocene PP2602 | 70 | 70 | 70 | | 80 | | | 80 | 90 | | 60 | |
| | Hiwax NP055 | 5 | 10 | 10 | 20 | | | | | | 80 | 30 | |
| | Arkon P125 | | 10 | | | | 5 | 15 | 10 | | 10 | | 20 |
| | I-MARV P125 | | | 5 | | 10 | | | | | | | |

In Table 1, “Tafthren H5002” is a propylenic elastomer (trade name “Tafthren H5002”, manufactured by Sumitomo Chemical, crystal melting energy: 11.3 J/g); “Licocene PP1602” is a polypropylene-based was (trade name “Licocene PP1602”, manufactured by Clariant, crystal melting energy: 26.9 J/g); “Licocene PP2602” is a polypropylene-based was (trade name “Licocene PP2602”, manufactured by Clariant, crystal melting energy: 39.8 J/g); “Hiwax NP055” is a polypropylene-based was (trade name “Hiwax NP055”, manufactured by Mitsui Chemical, crystal melting energy: 87.2 J/g); “Arkon P125” is a hydrogenated petroleum resin (trade name “Arkon P125”, manufactured by Arakawa Chemical Industry, softening point: 125° C.); “I-MARV P125” is a hydrogenated petroleum resin (trade name “I-MARV P125”, manufactured by Idemitsu Kosan, softening point: 125° C.).

### (Evaluation)

In Examples and Comparative Examples, the crystal melting energy of the pressure-sensitive adhesive layer, the pressure-sensitive adhesive force to acrylic plate thereof, the dust-proofness thereof, the reworkability thereof, as well as the melt viscosity and the heat resistance of the pressure-sensitive adhesive layer were measured and evaluated. The results are shown in Table 2.

### (Crystal Melting Energy of Pressure-Sensitive Adhesive Layer)

3.0 mg of the pressure-sensitive adhesive layer of the foam laminate was sampled to prepare a sample thereof.

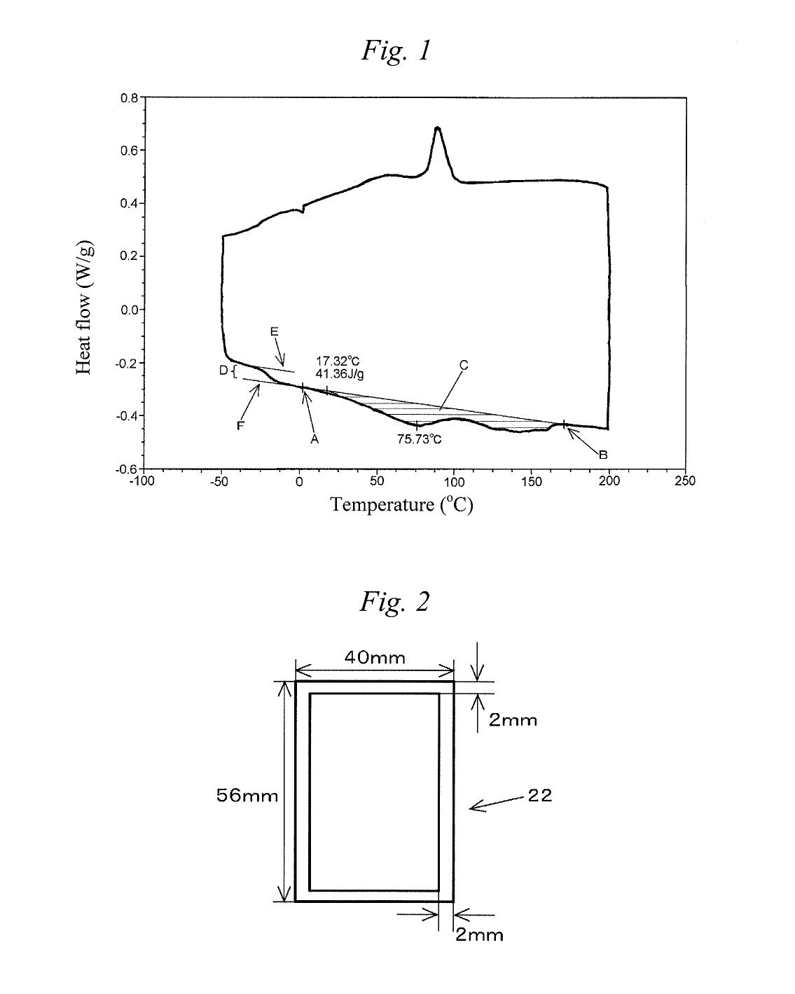

The sample was tested through differential scanning calorimetry (DSC measurement) under the condition mentioned below to obtain a DSC curve (for example, FIG. 1). The measurement was carried out according to JIS K 7122.

The sum total of the melting energy values at the 2nd run heating was calculated to be the crystal melting energy of the sample.

### DSC Condition

### Amount of Sample: 3.0 mg

Pan: Tzero pan (manufactured by TA Instruments) (diameter: 4 mm), Tzero top (manufactured by TA Instruments)

### Heating Rate: 10° C./min

### Cooling Rate: 10° C./min

### Temperature Profile:

1st run heating (first heating): heating from −50° C. up to 200° C.

1st run cooling (first cooling); cooling from 200° C. down to −50° C.

2nd run heating (second heating): heating from −50° C. up to 200° C.

In Comparative Example 1, the sample did not have a pressure-sensitive adhesive layer, and therefore the crystal melting energy measurement of pressure-sensitive adhesive layer was omitted.

The method for measurement of the crystal melting energy of pressure-sensitive adhesive layer is described further with reference to Example 3. FIG. 1 shows a chart (DSC curve) obtained in differential scanning calorimetry (DSC measurement) in Example 3.

First, the sample was melted by heating it from −50° C. up to 200° C. at a heating rate of 10° C./min. Next, the molten sample was solidified by cooling it from 200° C. down to −50° C. at a cooling rate of 10° C./min. Next, the solidified sample was again melted by heating it from −50° C. up to 200° C. at a heating rate of 10° C./min. The process of differential scanning calorimetry (DSC measurement) gave the DSC curve (see the chart in FIG. 1).

Next, on the DSC curve, the crystal melting energy was obtained from the area of the part (the shaded peak area in FIG. 1) surrounded by the line drawn by connecting the point to separate from the base line (point A in FIG. 1) before and after the melting peak (peak C in FIG. 1 (peak of the slant line in FIG. 1)) and the point to return back to the base line (point B in FIG. 1) and the melting peak.

The base line of the melting peak is the high-temperature side base line (base line F) of the low-temperature side base line (base line E in FIG. 1) and the high-temperature side base line (base line F in FIG. 1) in determining the glass transition temperature from the step-like change (step-like change D in FIG. 1) on the DSC curve.

### (Pressure-Sensitive Adhesive Force to Acrylic Plate)

The foam laminate was cut to obtain a test piece having a width of 20 mm and a length of 100 mm.

The test piece was stuck under pressure to an acrylic plate (trade name “Acrylite” manufactured by Mitsubishi Rayon) by applying thereto a 1-kg roller for once backward and forward rolling motion thereon, and then left at room temperature (23±2° C.) for 30 minutes.

After thus left, the test piece was tested in a peeling test (according to JIS Z 0237) under the condition of an atmosphere at a temperature of 23±2° C. and a humidity of 50±5 RH, and at a tension rate of 0.3 m/min and a peel angle of 180°, using a tensile tester (device name “TG-1kN”, manufactured by Minebea) thereby determining the pressure-sensitive adhesive force thereof to the acrylic plate (peeling strength from acrylic plate).

In Comparative Examples 1, 2 and 3, the samples did not exhibit adhesiveness even though adhered under pressure to the acrylic plate, and therefore the pressure-sensitive adhesive force thereof to the acrylic plate could not be measured. These samples were evaluated as “not adhered”.

### (Dynamic Dust-Proofness)

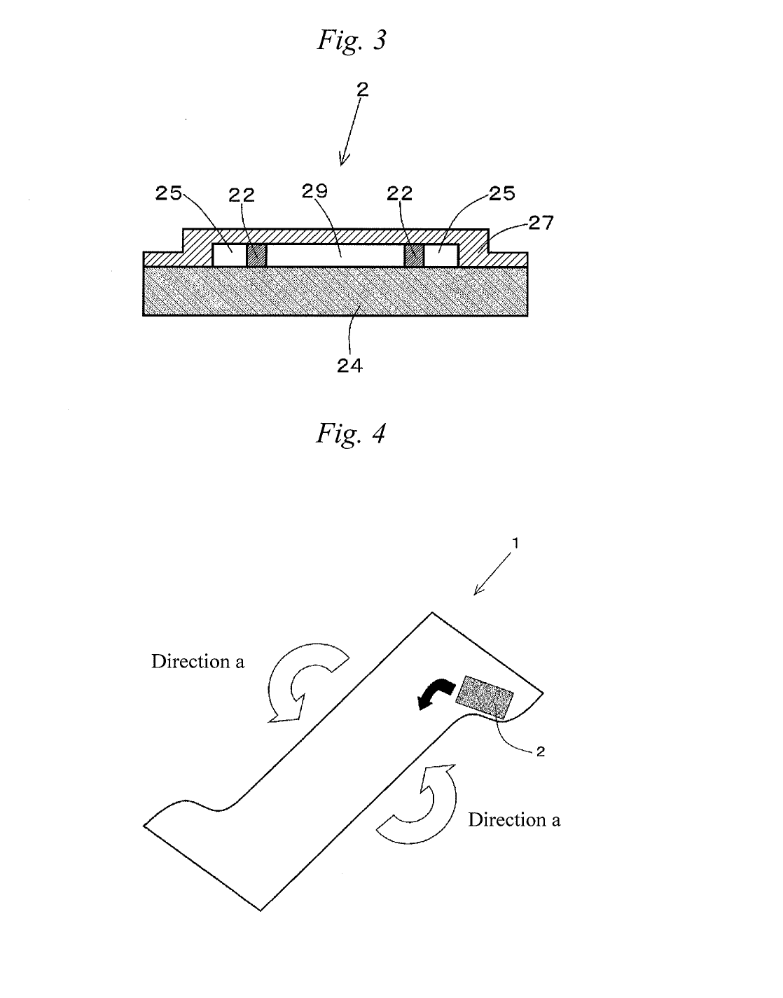

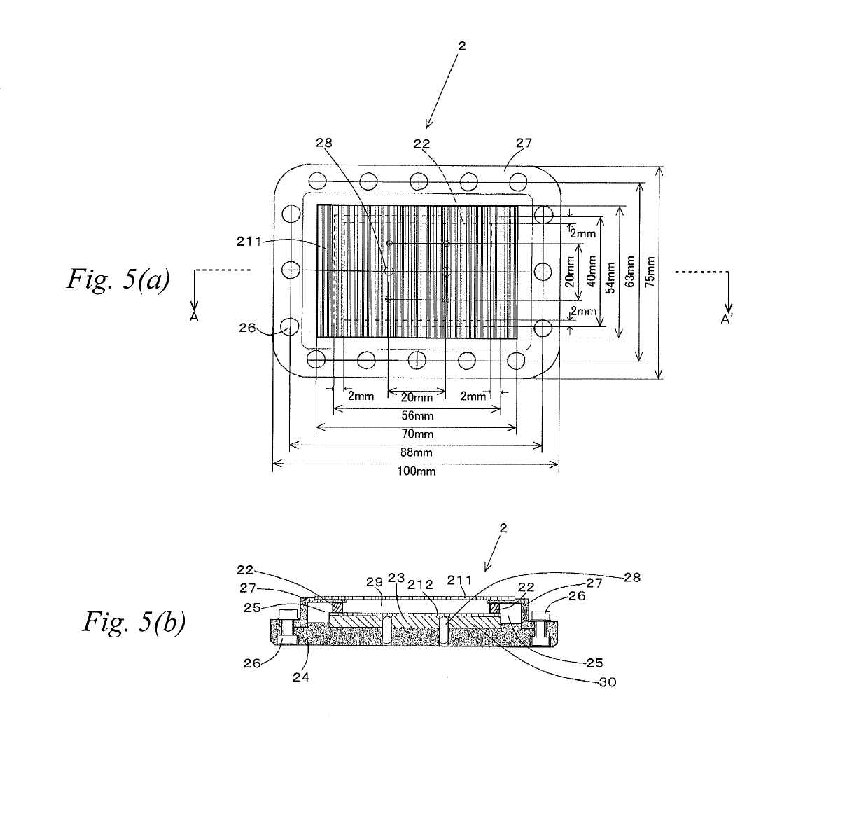

The foam laminate (the foam in Comparative Example 1) was punched out to obtain a frame-like sample (see FIG. 2), and, as shown in FIG. 3 and FIG. 5, set in an evaluation container (evaluation container for dynamic dust-proofness mentioned below—see FIG. 3 and FIG. 5). Next, a particulate substance was applied to the outside part (powder-supplying part) of the evaluation sample in the evaluation container, then the evaluation container to which the particulate substance had been applied was put in a tumbler (tumbling barrel), and the tumbler was rotated in a counterclockwise fashion to thereby load repeated impact to the evaluation container. With that, the number of the powder having passed through the evaluation sample and having penetrated into the inside of the evaluation container was counted to thereby evaluate the dynamic dust-proofness of the foam laminate.

FIGS. 5(a) and (b) show the top view and the cross-sectional edge view, respectively, of the evaluation container (evaluation container for evaluation of dynamic dust-proofness) with the evaluation sample set therein. FIG. 5(a) is the top view of the evaluation container for evaluation of dynamic dust-proofness with the evaluation sample set therein. FIG. 5(b) is a cross-sectional view of the edge of the evaluation container with the evaluation sample set therein, as cut along the A-A′ line in (a). The evaluation container was dropped down after the evaluation sample had been set therein, whereby the dynamic dust-proofness (dust-proofness under impact) of the evaluation sample could be evaluated. In FIGS. 5(a) and (b), the reference numeral 2 indicates the evaluation container with the evaluation sample set therein; the reference numeral 211 indicates a black acrylic plate (black acrylic plate on the side of a cover plate); the reference numeral 212 indicates a black acrylic plate (black acrylic plate on the side of an aluminium plate); the reference numeral 22 indicates the evaluation sample (frame-shaped resin foam); the reference numeral 23 indicates an aluminium plate; the reference numeral 24 indicates a base plate; the reference numeral 25 indicates the powder-supplying part; the reference numeral 26 indicates a screw; the reference numeral 27 indicates a foam compression plate; the reference numeral 28 indicates a pin; the reference numeral 29 indicates the inside of the evaluation container; the reference numeral 30 indicates an aluminium spacer. The compression ratio of the evaluation sample 22 can be controlled by changing the thickness of the aluminium spacer 30. Though omitted in the top view of the evaluation container for dynamic dust-proofness evaluation with the evaluation sample set therein shown in FIG. 5(a), a cover plate fixing tool is fitted between the facing screws so that the black acrylic plate 211 is firmly fixed to the foam compression plate 27.

FIG. 3 is a simple, schematic cross-sectional view of the evaluation container for dynamic dust-proofness evaluation with the evaluation sample set therein. In FIG. 3, the reference numeral 2 indicates the evaluation container with the evaluation sample set therein (package with the evaluation sample set therein); the reference numeral 22 indicates the evaluation sample (frame-like punched-out resin foam); the reference numeral 24 indicates the base plate; the reference numeral 25 indicates the powder-supplying part; the reference numeral 27 indicates the foam compression plate; the reference numeral 29 indicates the inside of the evaluation container (inside the package). In the evaluation container with the evaluation sample set therein in FIG. 3, the powder-supplying part 25 and the inside of the evaluation container 29 are partitioned from each other via the evaluation sample 22, and the powder-supplying part 25 and the inside of the evaluation container 29 each form a closed system.

FIG. 4 is a schematic view showing an evaluation method for dynamic dust-proofness test. In FIG. 4, the reference numeral 1 indicates a tumbler; the reference numeral 2 indicates the evaluation container with the evaluation sample set therein; and the direction a indicates the rotation direction of the tumbler. The evaluation container 2 is housed in the tumbler 1. When the tumbler 1 is rotated, impact is repeatedly given to the evaluation container 2 therein.

The dynamic dust-proofness evaluation method is described in more detail.

A resin foam is punched out into a frame-like (window frame-like) evaluation sample 22 (frame width: 2 mm) as shown in FIG. 2.

As shown in FIG. 3 and FIG. 5, the evaluation sample 22 is fitted to the evaluation container 2 (evaluation container for dynamic dust-proofness evaluation; see FIG. 3 and FIG. 5). The compression ratio of the evaluation sample 22 in fitting it to the container is 40% (that is, the sample is compressed so that its thickness could be 40% of the original thickness).

As shown in FIG. 5, the evaluation sample 22 is arranged between the foam compression plate 27 and the black acrylic plates 211 and 212 on the aluminium plate 23 fixed to the base plate 24. In the evaluation container 2 with the evaluation sample 22 set therein, the evaluation sample 22 forms a closed system in a given region inside the container.

As shown in FIG. 4, after the evaluation sample 22 has been set in the evaluation container 2, 0.1 g of a powder, corn starch (particle size: 17 μm) is put into the powder-supplying part 25, then the evaluation container 2 is put into the tumbler 1 (tumbling barrel, drum-type dropping tester), and the tumbler is rotated at a speed of 1 rpm.

After the tumbler has been rotated in a predetermined rotation frequency so that repetitive 100 collisions (repetitive impacts) could be given to the sample, the evaluation container (package) 2 was taken apart. Using a digital microscope (device name “VHX-600”, by Keyence), the particles having left from the powder-supplying part 25 and passed through the evaluation sample 22 to adhere to the black acrylic plate 212 on the aluminium plate 23 and to the black acrylic plate 211 serving as the cover plate are observed. Still images of the black acrylic plate 212 on the side of the aluminium plate 23 and the black acrylic plate 211 on the cover plate side are taken, and digitalized with image-analyzing software (software name “Win ROOF” manufactured by Mitani Corporation), and the number of the particles and the total area of the particles are determined. Image observation is carried out in a clean bench so as to evade the influence of floating dust in air.

The samples in which the total particle area of the particles adhering to the black acrylic plate 212 on the side of the aluminium plate 23 and the particles adhering to the black acrylic plate 211 on the cover plate side is less than 1500 [Pixel×Pixel] are evaluated as good “◯”; and the samples in which the total particle area is more than 1500 [Pixel×Pixel] are evaluated as not good “x”.

### (Melt Viscosity of Pressure-Sensitive Adhesive Layer)

20 g of the pressure-sensitive adhesive layer of the foam laminate was sampled to prepare a test piece. Next, the test sample was dissolved in a sample chamber at 200° C., and stirred with a rotor for 30 minutes to obtain a melt. The viscosity of the melt was measured to be the melt viscosity of the sample.

In Comparative Example 1, the sample did not have a pressure-sensitive adhesive layer, and therefore the melt viscosity measurement of pressure-sensitive adhesive layer was omitted.

Melt Viscosity Apparatus: “DV-II+ VISCOMETER” (manufactured by Brook Fild)

### Sample Chamber: HT-2 DB

### Rotor: SC4-27

### (Reworkability Evaluation Test)

The foam laminate was cut to obtain a test piece having a width of 20 mm and a length of 100 mm.

The test piece was adhered under pressure to an acrylic plate (trade name “Acrylite” manufactured by Mitsubishi Rayon) by applying thereto a 1-kg roller for once backward and forward rolling motion thereon, and then left at room temperature (23±2° C.) for 24 hours.

After thus left, the test piece was peeled in an atmosphere at a temperature of 23±2° C. and a humidity of 50±5 RH, and at a tension rate of 0.3 m/min and a peel angle of 180°, using a tensile tester (device name “TG-1kN”, manufactured by Minebea).

After peeled, the test piece and the surface of the acrylic plate from which the test piece had been peeled were visually observed to evaluate the reworkability (repeelability) of the sample according to the following criteria.

### Reworkability Evaluation Criteria

Good (◯): Nothing (no adhesive) remained on the surface of the acrylic plate from which the test piece had been peeled.

Not Good (x): Some matter (adhesive) remained on the surface of the acrylic plate from which the test piece had been peeled.

### (Heat Resistance)

The foam laminate was cut to obtain a test sample having a width of 30 mm and a length of 30 mm. Using a jig, the sample was uniformly compressed in the thickness direction so that its thickness could be 50% of the thickness thereof before compression. Next, the sample was, while kept compressed by 50% in the thickness direction, stored in an atmosphere at 80° C. for 72 hours. With that, the stored sample was visually observed and checked as to whether or not the pressure-sensitive adhesive layer in the foam laminate became fluidized and stepped out of the foam laminate.

The samples where the pressure-sensitive adhesive layer did not step out were evaluated as having good heat resistance (◯); while on the other hand, the samples where the pressure-sensitive adhesive layer stepped out were evaluated as being poor in heat resistance (x).

In all the tested samples, the pressure-sensitive layer did not step out of the foam laminate in the stage where the sample was compressed by 50% in the thickness direction before storage.

TABLE 2

| | Example | | | | | | | | | Comparative Example | | | |
|---|---|---|---|---|---|---|---|---|---|---|---|---|---|
| | 1 | 2 | 3 | 4 | 5 | 6 | 7 | 8 | 9 | 1 | 2 | 3 | 4 |
| Crystal Melting | 30.5 | 37.8 | 41.4 | 42.1 | 32.4 | 28.5 | 23.2 | 30.7 | 40.3 | — | 78.3 | 52.8 | 26.5 |
| Energy | | | | | | | | | | | | | |
| [J/g] | | | | | | | | | | | | | |
| Pressure-sensitive | 0.86 | 0.96 | 0.83 | 0.82 | 0.88 | 0.93 | 2.18 | 0.85 | 0.82 | “not | “not | “not | 2.90 |
| adhesive force to | | | | | | | | | | adhered” | adhered” | adhered” | |
| Acrylic Plate | | | | | | | | | | | | | |
| [N/20 mm] | | | | | | | | | | | | | |
| Dust-Proofness | — | ◯ | — | — | — | — | ◯ | — | ◯ | X | X | X | ◯ |
| Reworkability | ◯ | ◯ | ◯ | ◯ | ◯ | ◯ | ◯ | ◯ | ◯ | — | — | — | X |
| Melt Viscosity | 20.4 | 8.2 | 11.0 | 3.1 | 11.0 | 14.6 | 12.3 | 3.1 | 11.6 | — | 0.3 | 4.0 | 7.4 |
| [Pa · s] | | | | | | | | | | | | | |
| Heat Resistance | ◯ | ◯ | ◯ | ◯ | X | X | X | X | X | — | ◯ | ◯ | X |
| Proportion of | 5.0 | 11.1 | 10.5 | 20.0 | 0.0 | 0.0 | 0.0 | 0.0 | 0.0 | — | 800.0 | 42.9 | 0.0 |
| Polyolefin B | | | | | | | | | | | | | |
| [% by weight] | | | | | | | | | | | | | |

In the above Table 2, “-” means that the sample was not measured or evaluated. In Comparative Examples 1 to 3, the sample did not exhibit adhesiveness when adhered to an acrylic plate, and therefore could not be evaluated for the reworkability thereof.

The foam laminates of Examples 1 to 9 are peeled from the acrylic plate when the pressure-sensitive adhesive force thereof to the acrylic plate is measured or when the foam laminates are evaluated in the reworkability evaluation test, and in peeling them from the acrylic plate, all the foam laminates of those Examples safely peeled not causing breakage of the foam laminates such as breakage of the foam layer therein.

The invention has been described in detail with reference to specific embodiments thereof; however, it is obvious to those skilled in the art that various modifications and changes can be made in the invention not overstepping the spirit and the scope of the invention. The present application is based on a Japanese patent application filed on Jan. 24, 2011 (Application Number 2011-012249), and the contents thereof are hereby incorporated by reference.

### DESCRIPTION OF REFERENCE NUMERALS AND SIGNS

1 Tumbler
2 Evaluation Container Fitted With Evaluation Sample
22 Evaluation Sample
23 Aluminium Plate
24 Base Plate
25 Powder-Supplying Part
26 Screw
27 Foam Compression Plate
28 Pin
29 Inside of Evaluation Container
30 Aluminium Spacer
211 Black Acrylic Plate
212 Black Acrylic Plate

1. A foam laminate for electric or electronic devices having, on at least one side of a foam layer, a polyolefin-based pressure-sensitive adhesive layer containing a polyolefin, wherein the polyolefin-based pressure-sensitive adhesive layer has a 180° peelability from an acrylic plate (tension rate: 0.3 m/min) of from 0.1 N/20 mm to 2.5 N/20 mm.

2. The foam laminate for electric or electronic devices according to claim 1, wherein the polyolefin-based pressure-sensitive adhesive layer is a pressure-sensitive adhesive layer containing a polyolefin A having a crystal melting energy of less than 50 J/g, or a pressure-sensitive adhesive layer containing the polyolefin A and a polyolefin B having a crystal melting energy of 50 J/g or more in which a proportion of the polyolefin B is from 3 to 28% by weight with respect to a total polyolefin amount (100% by weight).

3. The foam laminate for electric or electronic devices according to claim 1, wherein the polyolefin-based pressure-sensitive adhesive layer is a hot-melt pressure-sensitive adhesive layer having a melt viscosity at 200° C. of from 1 to 30 Pa·s.

4. The foam laminate for electric or electronic devices according to claim 1, wherein the foam layer has an apparent density of from 0.02 to 0.30 g/cm³.

5. The foam laminate for electric or electronic devices according to claim 2, wherein the polyolefin-based pressure-sensitive adhesive layer is a hot-melt pressure-sensitive adhesive layer having a melt viscosity at 200° C. of from 1 to 30 Pa·s.

6. The foam laminate for electric or electronic devices according to claim 2, wherein the foam layer has an apparent density of from 0.02 to 0.30 g/cm³.

7. The foam laminate for electric or electronic devices according to claim 3, wherein the foam layer has an apparent density of from 0.02 to 0.30 g/cm³.

8. The foam laminate for electric or electronic devices according to claim 5, wherein the foam layer has an apparent density of from 0.02 to 0.30 g/cm³.
